(19) United States
(12) Patent Application Publication
(10) Pub. No.: US 2026/0157176 A1
(43) Pub. Date: Jun. 4, 2026

(54) METHODS AND APPARATUS FOR SUBSTRATE PROCESSING

(71) Applicant: Applied Materials, Inc., Santa Clara, CA (US)

(72) Inventor: Benjamin D. BRIGGS, Merrimack, NH (US)

(21) Appl. No.: 18/967,955

(22) Filed: Dec. 4, 2024

(51) Int. Cl. H01L 23/373; H01L 23/00

(52) U.S. Cl. CPC H10W 40/255; H10W 72/01338; H10W 72/01359; H10W 72/01371; H10W 72/321; H10W 72/352; H10W 90/734

(57) ABSTRACT

Methods and apparatus for substrate processing include: depositing a bulk layer of a dielectric material comprising a metal onto a device attached to a device substrate; depositing a graded layer of the dielectric material with a compositional gradient, onto the bulk layer; and depositing a bonding cap layer of the metal, having a purity of at least 99% by weight, onto the graded layer, wherein the graded layer has a dielectric gradient from substantially dielectric adjacent to the bulk layer to substantially conductive adjacent the bonding cap layer.

### FIELD

Embodiments of the present disclosure generally relate to methods and apparatus for substrate processing, and more particularly, to thermal interface materials and methods of forming thermal interface materials.

### BACKGROUND

Backside power delivery (BPD) is a semiconductor technology that relocates the power delivery network from the frontside to the backside of a substrate (e.g., a silicon wafer). Backside power delivery aims to improve power efficiency, performance, and design flexibility in integrated circuits (ICs). The move to backside power delivery has created thermal management challenges in advanced logic and memory (e.g., CMOS), especially with the advent of artificial intelligence applications demanding ever growing computing resources. More specifically, in some instances, BPD can result in an IC that is impacted by self-heating as a result of raising the total thermal resistance between the IC and a heatsink coupled to the IC.

Accordingly, the inventors have provided embodiments of apparatus and methods of forming thermal interface materials which can lower the thermal resistance between a device (e.g., an IC) and a heat sink.

### SUMMARY

Methods and apparatus for substrate processing are provided herein. In some embodiments, a method for substrate processing includes: depositing a bulk layer of a dielectric material comprising a metal onto a device attached to a device substrate; depositing a graded layer of the dielectric material with a compositional gradient, onto the bulk layer; and depositing a bonding cap layer of the metal, having a purity of at least 99 % by weight, onto the graded layer, wherein the graded layer has a dielectric gradient from substantially dielectric adjacent to the bulk layer to substantially conductive adjacent the bonding cap layer.

In some embodiments, a packaged device includes: a device having a first side and a second side opposite the first side; and a thermal interface material attached to the second side of the device, wherein the thermal interface material includes: a bulk layer of a dielectric material comprising a metal; a graded layer of the dielectric material on the bulk layer, the dielectric material having a compositional gradient; and a bonding cap layer of the metal on the graded layer, the metal having a purity of at least 99% by weight, wherein the graded layer has a dielectric gradient from substantially dielectric adjacent to the bulk layer to substantially conductive adjacent the bonding cap layer.

Other and further embodiments of the present disclosure are described below.

### BRIEF DESCRIPTION OF THE DRAWINGS

Embodiments of the present disclosure, briefly summarized above and discussed in greater detail below, can be understood by reference to the illustrative embodiments of the disclosure depicted in the appended drawings. However, the appended drawings illustrate only typical embodiments of the disclosure and are therefore not to be considered limiting of scope, for the disclosure may admit to other equally effective embodiments.

FIG. 1 is a flow chart showing a method in accordance with some embodiments of the present disclosure.

FIG. 2 is a flow chart showing a method in accordance with some embodiments of the present disclosure.

FIG. 3 shows a device attached to a device substrate in accordance with some embodiments of the present disclosure.

FIG. 4 shows a layer of bulk dielectric material deposited on the device shown in FIG. 3 in accordance with some embodiments of the present disclosure.

FIG. 5 shows a graded layer of dielectric material and a bonding cap layer deposited onto the bulk layer shown in FIG. 4 in accordance with some embodiments of the present disclosure.

FIG. 6 shows a bulk layer of dielectric material, a graded layer of dielectric material, and a bonding cap layer deposited on a carrier substrate.

FIG. 7 shows bonding between the bonding cap layer shown in FIG. 5 and the bonding cap layer shown in FIG. 6 in accordance with some embodiments of the present disclosure.

FIG. 8 shows removal of the device substrate shown in FIG. 7 in accordance with some embodiments of the present disclosure.

FIG. 9 shows connection of a back side power distribution network to the device and connection of a heat spreader interface to the carrier substrate shown in FIG. 8 in accordance with some embodiments of the present disclosure.

FIG. 10 shows bonding between the bonding cap layer shown in FIG. 5 and a carrier substrate in accordance with some embodiments of the present disclosure.

FIG. 11 shows removal of the device substrate shown in FIG. 10 in accordance with some embodiments of the present disclosure.

FIG. 12 shows connection of a back side power distribution network to the device and a heat spreader interface to the carrier substrate shown in FIG. 11 in accordance with some embodiments of the present disclosure.

FIG. 13 shows an example of a device with a front side power distribution network in accordance with some embodiments of the present disclosure.

To facilitate understanding, identical reference numerals have been used, where possible, to designate identical elements that are common to the figures. The figures are not drawn to scale and may be simplified for clarity. Elements and features of one embodiment may be beneficially incorporated in other embodiments without further recitation.

### DETAILED DESCRIPTION

Embodiments of an apparatus and method form forming a thermal interface material are provided herein that can lower the total thermal resistance between a device (e.g., an IC) and a heatsink, thereby reaping the routing and parasitic benefits of backside power distribution. Moreover, the methods and apparatus described herein may also be used with packaged devices having frontside power distribution. Embodiments of the methods described herein utilize sputter deposition processes to deposit layers of a multi-layer thermal interface structure having high thermal conductivity (e.g., 50-200 W/mK) and high bond strength (e.g., at least 2.1 J/m). Specifically, embodiments of the thermal interface structure include a bulk layer of a dielectric material comprising a metal, a graded layer of the dielectric material with a compositional gradient, and a bonding cap layer of the metal having a purity of at least 99% by weight onto the graded layer. The methods and apparatus described herein are advantageous over conventional SiO2 and SiCN based films having lower thermal conductivity. Specifically, the thermal interface materials deposited using the methods described herein have a thermal conductivity that is more than 100 times the thermal conductivity of conventional SiO2 and SiCN based films.

Moreover, the methods and apparatus described herein provide sufficient bond strength for backside power distribution as well as front side power distribution. AlN offers high thermal conductivity (achieved by vertically oriented columnar grain structure) and has been proposed as a possible thermal interface material for backside power delivery applications. However, a natural consequence of the vertically oriented columnar grain structure of AlN is very high surface roughness, negatively impacting bond strength and increasing thermal interface resistance. Direct CMP of the AlN to smooth the AlN surface utilizing known slurry chemistries has not been successful and adds considerable cost of ownership. Moreover, while a “gap fill” oxide layer deposited atop the AlN to fill in the surface roughness and present a surface that can be planarized (e.g., with CMP) can be implemented, the deposited oxide layer reduces the total thermal conductivity of the thermal interface structure. The deposition of the bonding cap layer that is substantially metal (having a purity of at least 99% by weight), provides a bonding surface that can be planarized to a surface roughness sufficient for high bond strength and a material that does not reduce the total thermal conductivity of the thermal interface structure.

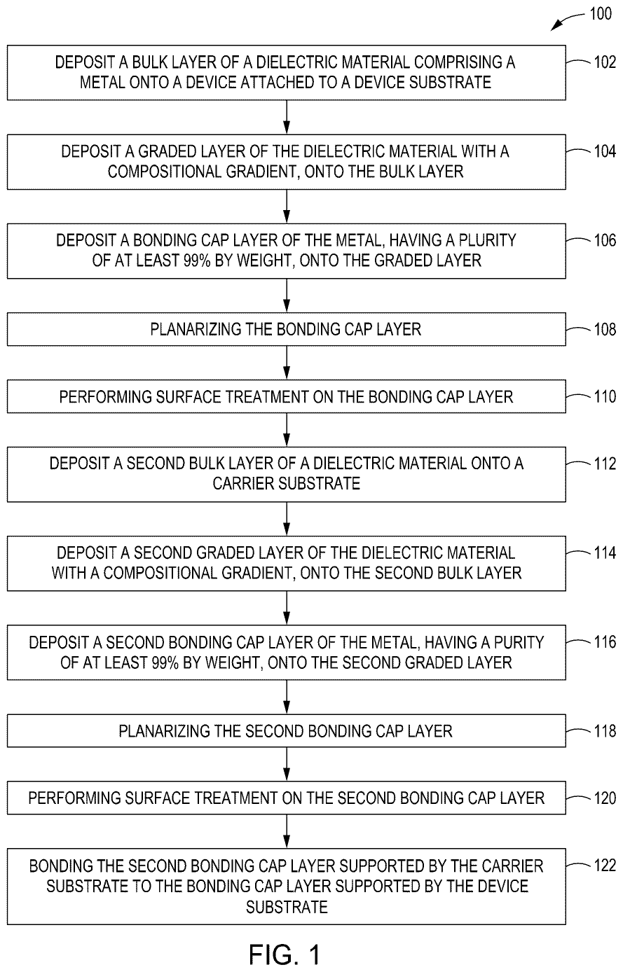

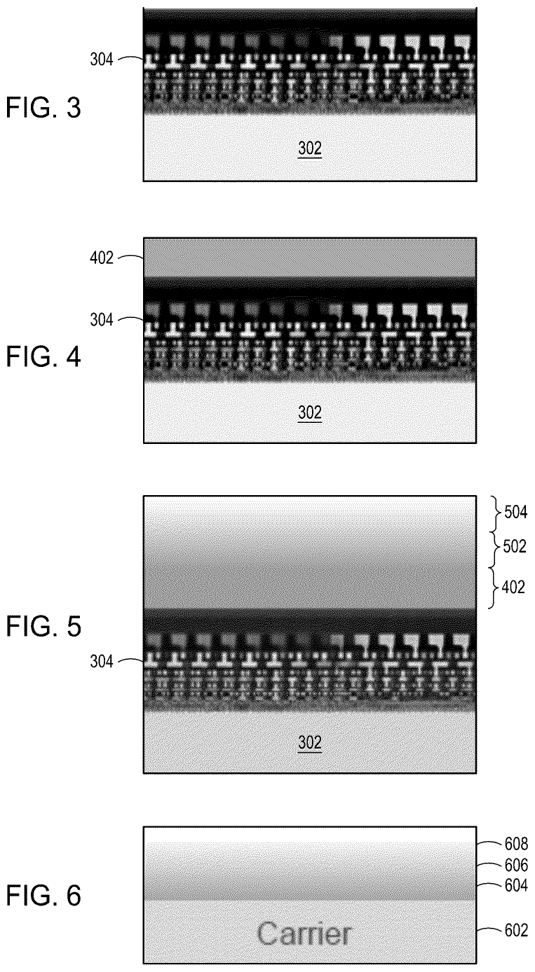

FIG. 1 is a flow chart showing a method 100 of substrate processing in accordance with some embodiments of the present disclosure. At block 102, the method 100 includes depositing a bulk layer of a dielectric material comprising a metal onto a device attached to a device substrate. FIG. 3 shows a device substrate 302 attached to a device 304 (e.g., an IC). The device substrate 302 may be a silicon substrate. FIG. 4 shows a bulk layer 402 of dielectric material deposited on the device 304 shown in FIG. 3.

At block 104, the method 100 includes depositing a graded layer of the dielectric material with a compositional gradient, onto the bulk layer. In some embodiments, the compositional gradient includes a progressively higher percent by weight of the metal in a direction moving away from the bulk layer. At block 106, the method 100 includes depositing a bonding cap layer of the metal, onto the graded layer. The graded layer has a dielectric gradient from substantially dielectric adjacent to the bulk layer to substantially conductive adjacent the bonding cap layer. FIG. 5 shows a graded layer 502 of dielectric material and a bonding cap layer 504 deposited onto the bulk layer 402 shown in FIG. 4. In some embodiments, the bulk layer, the graded layer, and the bonding cap layer are deposited in one deposition chamber.

At block 108, the method 100 may include planarizing the bonding cap layer 504. Planarizing may be performed by a CMP process. The bonding cap layer 504 may be planarized to achieve a surface roughness of 0.5 nm to 1 nm, which is suitable for fusion bonding.

In some embodiments, the bulk layer 402, the graded layer 502, and the bonding cap layer 504 may include aluminum, and each of the bulk layer 402, the graded layer 502, and the bonding cap layer 504 may have a thermal conductivity of at least 50 W/mK. The thicknesses of the bulk layer 402, the graded layer 502, and the bonding cap layer 504 may be selected to be sufficient to ensure adequate lateral and vertical heat conduction. In some embodiments, at least one of the bulk layer 402 is 10 nm to 1 micron, the graded layer 502 is 1 nm to 1 micron, or the bonding cap layer 504 is 10 nm to 300 nm.

In some embodiments, the bulk layer 402 and the graded layer 502 may be comprised of a metal nitride or a metal oxide and the bonding cap layer 504 may be comprised of the metal of the metal nitride or the metal oxide.

In some embodiments, depositing the bulk layer 402 may include depositing AlN onto the device 304 attached to the device substrate 302, depositing the graded layer 502 may include depositing AlNₓ onto the bulk layer, where x is between 0 and 1 and wherein x varies with thickness of the graded layer 502, and depositing the bonding cap layer 504 may include depositing a layer of Al having a purity of at least 99% by weight onto the graded layer. In some embodiments, x=0 at an interface between the bonding cap layer 504 and the graded layer 502, and x=1 at an interface between the bulk layer 402 and the graded layer 502.

In some embodiments, the deposition of the bulk layer 402, the graded layer 502, and the bonding cap layer 504 are performed by sputter deposition (e.g., plasma vapor deposition, PVD) in a PVD chamber. In some embodiments, the PVD chamber may be an impulse PVD chamber configured for performing an impulse PVD or high power impulse magnetron sputtering process. An example of an impulse PVD chamber is a chamber of the Endura® Impulse™ PVD system manufactured by Applied Materials of Santa Clara, California.

In some embodiments, depositing the bulk layer 402 may include sputter depositing (e.g., in a PVD chamber) metal nitride (e.g., AlN) using a metal target (e.g., Al) in a nitrogen atmosphere, depositing the graded layer 502 may include sputter depositing metal nitride onto the bulk layer 402 while reducing nitrogen gas flow to zero over a first period of time to form the graded layer 502, and depositing the bonding cap layer 504 may include sputter depositing the metal (e.g., having a purity of at least 99% by weight) onto the graded layer 502 to form the bonding cap layer 504. In some embodiments, reducing the nitrogen gas flow may include tuning the nitrogen partial pressure near the end of metal nitride deposition to zero while continuing to supply power to the metal target to deposit the metal of bonding cap layer 504. When the partial pressure of nitrogen is reduced to zero and power remains supplied to the metal target, target nitrogen poisoning will occur, after which substantially metal (at least 99% by weight metal) will be sputter deposited.

When the metal nitride is AlN and the metal is Al, the graded layer 502 and the bonding cap layer 504 serve to transition between rough polycrystalline AlN and the metal bonding interface. The total thermal conductivity of the multilayer structure comprised of the AIN bulk layer 402/AlN graded layer 502/Al bonding cap layer 504 achieves the aforementioned thermal conductivity improvement over conventional SiO2 and SiCN based films and results in a bonding surface of the bonding cap layer 504 that can be planarized for a strong metal/metal bond.

At block 112, the method 100 may include depositing a second bulk layer of a dielectric material onto a carrier substrate. The carrier substrate may be comprised of silicon. The dielectric material of the second bulk layer may be the same as the dielectric material of the bulk layer deposited in block 102. The dielectric material of the second bulk layer may comprise a metal, which may be the same metal of the dielectric material of the bulk material deposited in block 102. At block 114, the method 100 may include depositing a second graded layer of the dielectric material (of the second bulk layer) with a compositional gradient, onto the second bulk layer. At block 116, the method 100 may include depositing a second bonding cap layer of the metal, having a purity of at least 99% percent by weight, onto the second graded layer. The depositing of the second bulk layer, the second graded layer, and the second bonding cap layer may be performed in the same way as described above with respect to blocks 102-106. For example, deposition of the second bulk layer, the second graded layer, and second bonding cap layer may be performed by sputter deposition processes as described above. In some embodiments, the second bulk layer, the second graded layer, and the second bonding cap layer are deposited in one deposition chamber. FIG. 6 shows a carrier substrate 602 with a second bulk layer 604 of dielectric material, a second graded layer 606 of the dielectric material, and a second bonding cap layer 608 deposited on the carrier substrate 602.

At block 118, the method 100 may include planarizing the second bonding cap layer 608. Planarizing may be performed by a CMP process. The second bonding cap layer 608 may be planarized to achieve a surface roughness of 0.5 nm to 1 nm to facilitate fusion bonding.

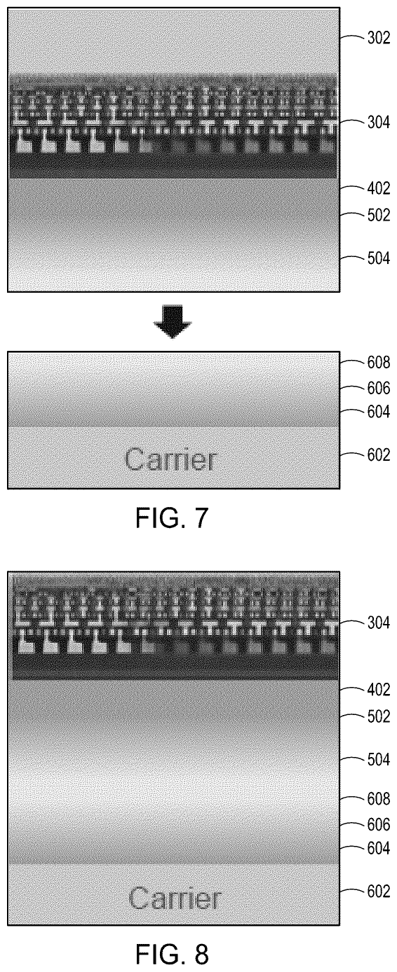

At block 122, the method 100 may include bonding the second bonding cap layer 608 supported by the carrier substrate 602 to the bonding cap layer 504 supported by the device substrate 302. Bonding may be performed by fusion bonding. FIG. 7 shows bonding between the bonding cap layer 504 shown in FIG. 5 and the second bonding cap layer 608 shown in FIG. 6.

At block 110, the method may include performing surface treatment on the bonding cap layer 504 before bonding. At block 120, the method 100 may include performing surface treatment on the second bonding cap layer 608 before bonding. The surface treatment may include a plasma activation treatment and/or oxide reduction reactions to remove any oxide layers that may be formed by passivation.

In some embodiments where the second bonding cap layer 608 and the bonding cap layer 504 are formed substantially of Al, a passivation layer of Al₂O₃ may be formed in ambient conditions. The formation of the passivation layer may result in the inability to generate Al grain growth across the surface of the Al₂O₃ without using extremely high bonding temperature and pressures. In some embodiments, high-vacuum bonding systems, such as the ComBond® systems manufactured by EV Group of St. Florian am Inn, Austria, can perform surface treatments (oxide reduction reactions) to reduce or eliminate the passivation layer and perform bonding while under high vacuum. In addition, the bonding temperatures in accordance with some embodiments may be around 100 C, which is lower than for bonding using conventional oxide/oxide fusion bonding. As a result, the methods in accordance with the present disclosure can result in a reduction in thermal budget for bonding in comparison to conventional oxide/oxide fusion bonding.

In some embodiments, and as shown in FIG. 8, the method 100 may include removing the device substrate 302 shown in FIG. 7. The device substrate 302 may be removed by various methods, such as, for example, grinding, CMP, or reactive ion etching.

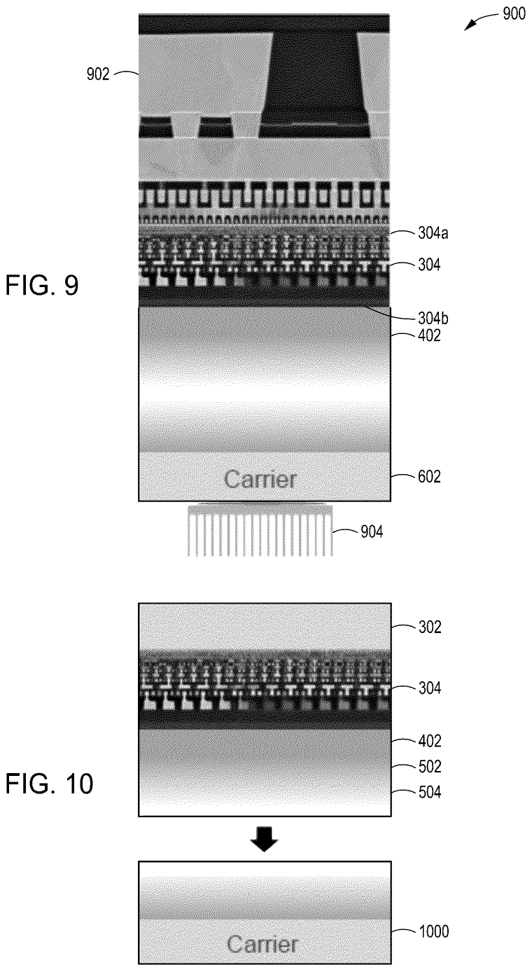

In some embodiments, and as shown in FIG. 9, the method 100 may include connecting a backside power distribution network 902 to a first side 304a of the device 304. The first side 304a is opposite to a second side 304b of the device 304. The second side 304b is attached to the bulk layer 402. Also, as shown in FIG. 9, the method 100 may include connecting a heatsink 904 to the carrier substrate 602 shown in FIG. 8. When connected to the heatsink 904, the carrier substrate 602 may function as a heat spreader interface to conduct heat from the device 304 to the heatsink 904. The completed structure shown in FIG. 9 may thus be referred to as a packaged device 900 having backside power delivery.

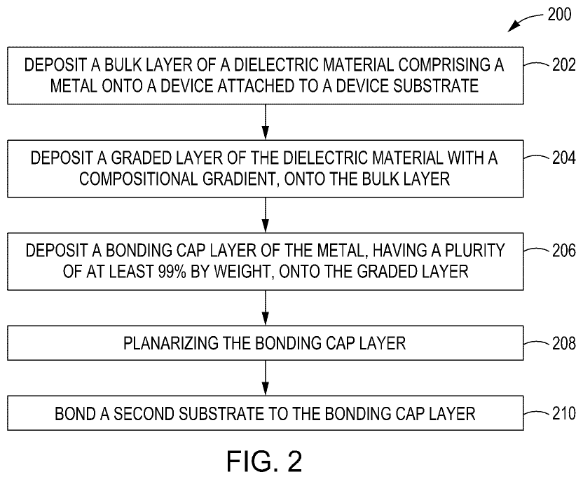

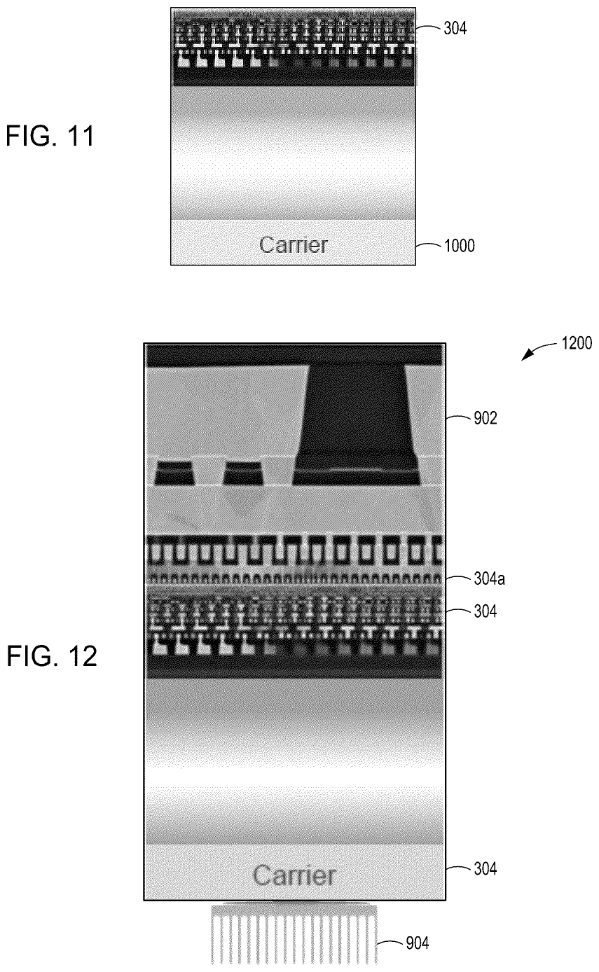

FIG. 2 shows another method 200 of substrate processing in accordance with some embodiments of the present disclosure. Blocks 202-208 are the same as blocks 102-108 of the method 100 described above. At block 210, the method may include bonding a carrier substrate (silicon substrate) or second substrate (e.g., directly) to the bonding cap layer, and without depositing any thermal interface material onto the carrier before bonding. FIG. 10 shows the bonding cap layer 504 being bonded to a carrier substrate 1000. In some embodiments, and as shown in FIG. 11, the method 200 may include removing the device substrate shown in FIG. 10.

In some embodiments, where the bonding cap layer 504 is formed of substantially Al and the carrier substrate 1000 is formed of substantially silicon, an Al₂O₃ passivation layer may be formed on the bonding cap layer 504 and a SiO₂ passivation layer may be formed on the carrier substrate 1000. The Al₂O₃ layer and the SiO₂ may be fusion bonded together without removing the oxide layers prior to bonding.

In some embodiments, and as shown in FIG. 12, the method 200 may include connecting a backside power distribution network 902 to the first side 304a of the device 304. Also, as shown in FIG. 12, the method 200 may include connecting the heatsink 904 to the carrier substrate 1000. When connected to the heatsink 904, the carrier substrate 1000 may function as a heat spreader interface to conduct heat from the device 304 to the heatsink 904. The completed structure shown in FIG. 12 may thus be referred to as a packaged device 1200 having backside power delivery.

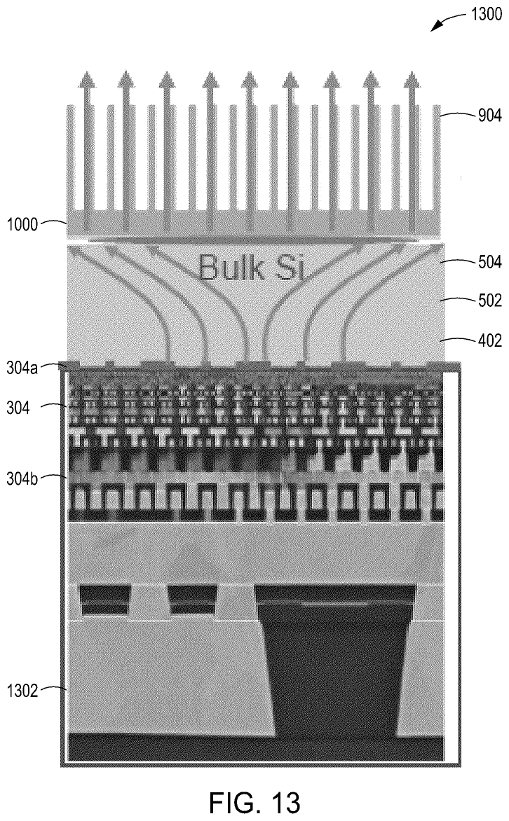

FIG. 13 shows an embodiment of a packaged device 1300 similar to packaged device 1200, but where a frontside power distribution network 1302 is on the second side 304b of the device 304.

Embodiments of apparatus and methods for substrate processing have been described that form thermal interface materials for packaged devices that can increase thermal conductivity over conventional SiO2 and SiCN based films and also lower the thermal budget for bonding.

While the foregoing is directed to embodiments of the present disclosure, other and further embodiments of the disclosure may be devised without departing from the basic scope thereof.

1. A method of substrate processing, comprising:
depositing a bulk layer of a dielectric material comprising a metal onto a device attached to a device substrate;
depositing a graded layer of the dielectric material with a compositional gradient, onto the bulk layer; and
depositing a bonding cap layer of the metal, having a purity of at least 99% by weight, onto the graded layer,
wherein the graded layer has a dielectric gradient from substantially dielectric adjacent to the bulk layer to substantially conductive adjacent the bonding cap layer.

2. The method of claim 1, wherein the bulk layer, the graded layer, and the bonding cap layer include aluminum, and wherein each of the bulk layer, the graded layer, and the bonding cap layer has a thermal conductivity of at least 50 W/mK.

3. The method of claim 1, wherein:
depositing the bulk layer includes depositing AlN onto the device attached to the device substrate,
depositing the graded layer includes depositing AlNₓ onto the bulk layer, where x is between 0 and 1 and wherein x varies with thickness of the graded layer, and
depositing the bonding cap layer includes depositing an aluminum (Al) layer, having a purity of at least 99% by weight, onto the graded layer.

4. The method of claim 1, wherein at least one of the bulk layer is 10 nm to 1 micron, the graded layer is 1 nm to 1 micron, or the bonding cap layer is 10 nm to 300 nm.

5. The method of claim 1, wherein the bulk layer and the graded layer are comprised of metal nitride or metal oxide and the bonding cap layer is comprised of the metal of metal nitride or metal oxide.

6. The method of claim 1, wherein:
depositing the bulk layer includes sputter depositing metal nitride using a metal target in a nitrogen atmosphere,
depositing the graded layer includes sputter depositing metal nitride onto the bulk layer while reducing nitrogen gas flow to zero over a first period of time to form the graded layer, and
depositing the bonding cap layer includes sputter depositing the metal having a purity of at least 99% by weight onto the graded layer to form the bonding cap layer.

7. The method of claim 1, wherein the bulk layer, the graded layer, and the bonding cap layer are deposited in one deposition chamber.

8. The method of claim 1, comprising:
depositing a second bulk layer of a dielectric material onto a carrier substrate;
depositing a second graded layer of the dielectric material with a compositional gradient, onto the second bulk layer;
depositing a second bonding cap layer of the metal, having a purity of at least 99% percent by weight, onto the second graded layer; and
bonding the second bonding cap layer supported by the carrier substrate to the bonding cap layer supported by the device substrate.

9. The method of claim 8, wherein:
depositing the second bulk layer includes depositing AlN onto the carrier substrate,
depositing the second graded layer includes depositing AlNₓ onto the second bulk layer, where x is between 0 and 1 and wherein x varies with thickness of the graded layer, and
depositing the second bonding cap layer includes depositing Al having a purity of at least 99% by weight onto the second graded layer.

10. The method of claim 9, comprising performing surface treatment on the second bonding cap layer supported by the carrier substrate and performing surface treatment on the bonding cap layer supported by the device substrate before bonding.

11. The method of claim 1, comprising bonding a second substrate to the bonding cap layer.

12. A packaged device, comprising:
a device having a first side and a second side opposite the first side; and
a thermal interface material attached to the second side of the device, wherein the thermal interface material includes:
a bulk layer of a dielectric material comprising a metal;
a graded layer of the dielectric material on the bulk layer, the dielectric material having a compositional gradient; and
a bonding cap layer of the metal on the graded layer, the metal having a purity of at least 99% by weight,
wherein the graded layer has a dielectric gradient from substantially dielectric adjacent to the bulk layer to substantially conductive adjacent the bonding cap layer.

13. The packaged device of claim 12, wherein the bulk layer, the graded layer, and the bonding cap layer include aluminum, and wherein the bulk layer, the graded layer, and the bonding cap layer each have a thermal conductivity of at least 50 W/mK.

14. The packaged device of claim 12, wherein:
the bulk layer includes AlN,
the graded layer includes AlNₓ, where x is between 0 and 1 and wherein x varies with thickness of the graded layer, and
the bonding cap layer includes Al having a purity of at least 99% by weight.

15. The packaged device of claim 12, wherein at least one of:
the bulk layer is 10 nm to 1 micron,
the graded layer is 1 nm to 1 micron,
the bonding cap layer is 10 nm to 300 nm, or
the bonding cap layer has a roughness of 0.5 nm to 1 nm.

16. The packaged device of claim 12, comprising a backside power distribution network on the first side of the device.

17. The packaged device of claim 12, comprising a frontside power distribution network on the second side of the device.

18. The packaged device of claim 12, comprising:
a carrier substrate;
a second bulk layer of a dielectric material comprising a metal on carrier substrate;
a second graded layer of the dielectric material with a compositional gradient on the second bulk layer; and
a second bonding cap layer of the metal having a purity of at least 99% by weight on the second graded layer,
wherein the second bonding cap layer supported by the carrier substrate is bonded to the bonding cap layer supported by the device.

19. The packaged device of claim 18, wherein:
the second bulk layer includes AlN,
the second graded layer includes AlNₓ, where x is between 0 and 1 and wherein x varies with thickness of the second graded layer, and
the second bonding cap layer includes Al having a purity of at least 99% by weight.

20. The packaged device of claim 12, comprising a silicon substrate bonded to the bonding cap layer.
